(19) United States
(12) Patent Application Publication
(10) Pub. No.: US 2025/0372572 A1
(43) Pub. Date: Dec. 4, 2025

(54) INTEGRATED CIRCUIT PACKAGES AND METHODS

(71) Applicant: Taiwan Semiconductor Manufacturing Co., Ltd., Hsinchu (TW)

(72) Inventors: Sheng-Han Tsai, Hsinchu (TW); Tsung-Yu Chen, Hsinchu (TW); Wensen Hung, Zhubei City (TW); Yen-Pu Chen, Hsinchu (TW)

(21) Appl. No.: 18/733,053

(22) Filed: Jun. 4, 2024

(51) Int. Cl. H01L 23/00; H01L 25/065

(52) U.S. Cl. CPC H01L 24/80; H01L 24/08; H01L 25/0652; H01L 24/06; H01L 2224/06051; H01L 2224/06505; H01L 2224/08145; H01L 2224/80365; H01L 2224/80379

(57) ABSTRACT

An integrated circuit package and the method of forming the same are provided. The integrated circuit package may include a first die. The first die may include a first semiconductor substrate, a first bonding layer over the first semiconductor substrate, and a first die connector in the first bonding layer. The first bonding layer may include a first portion including a first material and a second portion including a second material, wherein the first material is different from the second material. A surface of the first bonding layer may include a surface of the first portion, a surface of the second portion, and a surface of the first die connector.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, and 1F illustrate cross-sectional views and bottom-up views of an integrated circuit die, in accordance with some embodiments.

FIGS. 2A, 2B, 2C, 2D, 2E, 2F, 3, 4, 5, 6, 7, 8, 9, and 10 illustrate cross-sectional views and top-down views of intermediate processing steps in the formation of an integrated circuit package, in accordance with some embodiments.

FIG. 11 illustrates a cross-sectional view of an integrated circuit package, in accordance with some embodiments.

FIG. 12 illustrates a cross-sectional view of an integrated circuit package, in accordance with some embodiments.

FIG. 13 illustrates a cross-sectional view of an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated circuit packages and methods of forming the same are provided. In accordance with some embodiments, an integrated circuit package may comprise one or more upper integrated circuit dies bonded to a lower integrated circuit die. The upper integrated circuit dies may comprise heterogeneous bonding layers having different materials. The lower integrated circuit die may comprise a heterogeneous bonding layer having different materials. By bonding the heterogeneous bonding layers of the upper integrated circuit dies and the heterogeneous bonding layer of lower integrated circuit die using certain bonding configurations, improved bonding interfaces between the upper integrated circuit dies and the lower integrated circuit die may be obtained. As a result, the heat generated by the lower integrated circuit die may be more effectively dissipated during operation, thereby improving the performance and the reliability of the integrated circuit package.

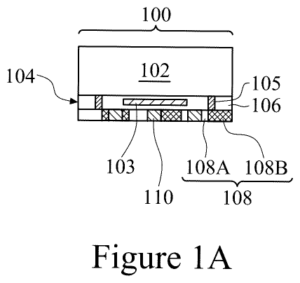

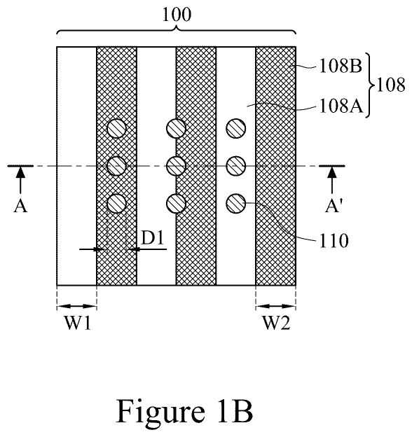

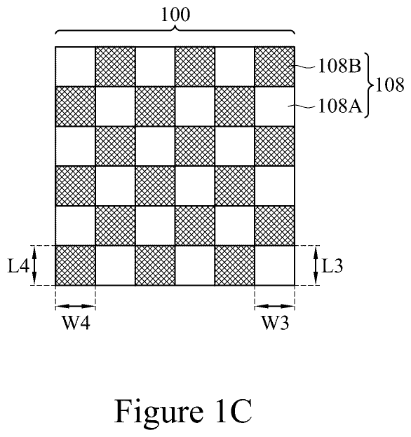

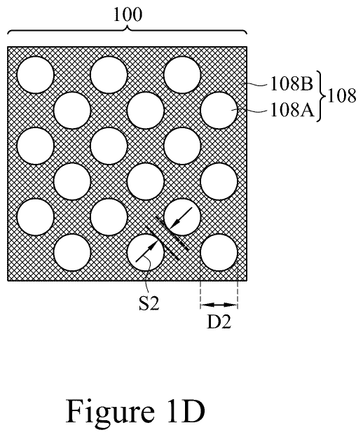

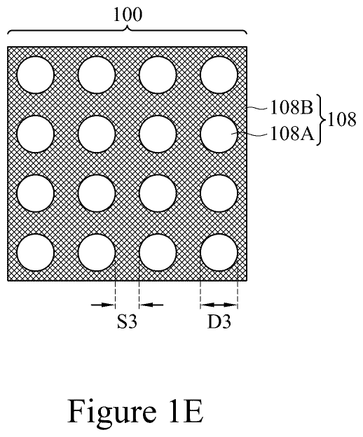

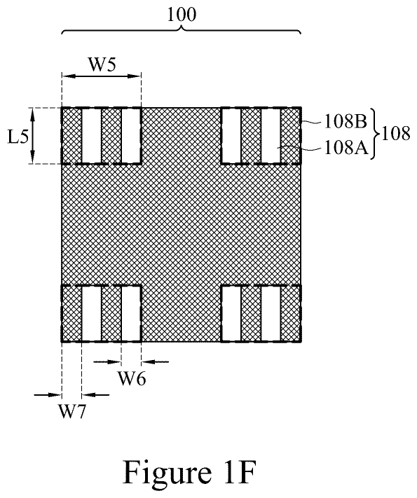

In FIGS. 1A and 1B, an upper integrated circuit die 100 is shown. The cross-sectional view shown in FIG. 1A may be obtained along reference cross-section A-A′ in the bottom-up view shown in FIG. 1B. The upper integrated circuit die 100 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), the like, or combinations thereof.

The upper integrated circuit die 100 may have a semiconductor substrate 102, such as doped silicon, undoped silicon, an active layer of a semiconductor-on-insulator (SOI) substrate, or the like. The semiconductor substrate 102 may include other semiconductor materials, such as germanium, silicon carbide, gallium arsenic, gallium phosphide, indium phosphide, indium arsenide, indium antimonide, SiGe, GaAsP, AlInAs, AlGaAs, GaInAs, GaInP, and/or GaInAsP, or combinations thereof. Other substrates, such as multi-layered or gradient substrates, may also be used. The semiconductor substrate 102 may have an active surface (e.g., the surface facing downwards in FIG. 1A), which may be called a front side, and an inactive surface (e.g., the surface facing upwards in FIG. 1A), which may be called a back side. The back side of the semiconductor substrate 102 may also be referred to as a back side of the upper integrated circuit die 100 and the front side of the semiconductor substrate 102 may face a front side of the upper integrated circuit die 100.

Devices (not separately illustrated) may be disposed at the active surface of the semiconductor substrate 102. The devices may be active devices (e.g., transistors, diodes, etc.), capacitors, resistors, or the like. The devices may generate a large amount of heat during operation. An interconnect structure 104 may be disposed on the active surface of the semiconductor substrate 102. The interconnect structure 104 may interconnect the devices to form an integrated circuit of the upper integrated circuit die 100. The interconnect structure 104 may comprise metallization patterns 103 in dielectric layers 106. The dielectric layers 106 may be low-k dielectric layers comprising suitable dielectric materials, such as silicon dioxide, silicon nitride, silicon oxynitride, or the like. The dielectric layers 106 may be formed by a suitable deposition process, such as chemical vapor deposition (CVD), high-density plasma chemical vapor deposition (HDP-CVD), atomic layer deposition (ALD), or the like. The metallization patterns 103 may include metal lines and vias, which may be formed in the dielectric layers 106 by a damascene process, such as a single damascene process, a dual damascene process, or the like. The metallization patterns 103 may be formed of a suitable conductive material, such as copper, tungsten, aluminum, silver, gold, a combination thereof, or the like. The metallization patterns 103 may be electrically coupled to the devices.

The interconnect structure 104 may further comprise a seal ring 105 in the dielectric layers 106. The seal ring 105 is shown in dash lines in FIG. 1C for illustrative purposes. In some embodiments, the seal ring 105 extends through the dielectric layers 106. The seal ring 105 may encircle the metallization patterns 103 in a bottom-up view and a region between the seal ring 105 and sidewalls of the interconnect structure 104 may be referred to as a keep-out zone (KOZ) of the interconnect structure 104. The KOZ may be free of the metallization patterns 103. The seal ring 105 may be formed of the same or similar material and by the same or similar process as the metallization patterns 103. The seal ring 105 may be electrically isolated from the integrated circuit of the upper integrated circuit die 100.

A bonding layer 108 may be disposed on the interconnect structure 104 at the front side of the upper integrated circuit die 100. The bonding layer 108 may be a heterogeneous bonding layer. The bonding layer 108 may comprise first portions 108A and second portions 108B arranged in an alternating pattern. A surface of the bonding layer 108 may comprise surfaces of the first portions 108A and surfaces of the second portions 108B. Each first portion 108A may be disposed beside one or more second portions 108B, wherein sidewalls of each first portion 108A may be in contact with sidewalls of the neighboring second portion(s) 108B. The first portions 108A and second portions 108B may comprise different materials, which may be selected from silicon oxide (e.g., a tetraethyl orthosilicate (TEOS) based silicon oxide), un-doped silicate glass (USG), silicon nitride, silicon oxynitride, or the like. The bonding layer 108 may be used for bonding with a bonding layer of another integrated circuit die in a subsequent process. The patterns and compositions of the first portions 108A and the second portions 108B may lead to a reduced bonding speed between the upper integrated circuit die 100 and the other integrated circuit die, which may lead to an improved bonding interface between the upper integrated circuit die 100 and the other integrated circuit die, as discussed in greater details below.

The bonding layer 108 may be formed by first forming a first layer comprising the material of the first portions 108A using a suitable deposition technique, such as CVD, HDP-CVD, ALD, or the like. Then the first layer may be patterned using a suitable photolithography technique to form the first portions 108A and openings. The second portions 108B may be formed using a suitable deposition technique, such as CVD, HDP-CVD, ALD, or the like, in the openings. Afterwards, a thinning process, such as a chemical-mechanical polishing (CMP) process, a grinding process, an etch-back process, combinations thereof, or the like may be used to expose the first portions 108A, and planarize surfaces of the first portions 108A and the second portions 108B. After the thinning process, the surfaces of the first portions 108A and the second portions 108B may be substantially coplanar (within process variations). In some embodiments, the first portions 108A and the second portions 108B are in contact with the interconnect structure 104. The above description with respect to forming the bonding layer 108 is provided as an example. In other embodiments, the second portions 108B may be formed before the first portions 108A.

As shown in FIG. 1B, the first portions 108A and the second portions 108B of the bonding layer 108 may be arranged in a grating pattern of alternating first portions 108A and second portions 108B. Each first portion 108A and each and second portion 108B may be in a shape of a strip extending from one edge of the upper integrated circuit die 100 to an opposing edge of the upper integrated circuit die 100. The first portions 108A may have a width W1 in a range from about 20 m to about 100 μm and the second portions 108B may have a width W2 in a range from about 20 m to about 100 μm. In some embodiments, the width W1 equals to the width W2.

Die connectors 110 may be disposed in the bonding layer 108. The die connectors 110 may be also referred to as bonding pads and may be used for bonding with another integrated circuit die in a subsequent process. The die connectors 110 may be electrically coupled with the metallization patterns 103 and the integrated circuit of the upper integrated circuit die 100. The die connectors 110 and the dummy die connectors 111 may be formed by one or more damascene processes, such as single damascene processes, dual damascene processes, or the like. The die connectors 110 may be formed of a suitable conductive material, such as copper, aluminum, or the like.

In the embodiments shown in FIGS. 1A and 1B, some of the die connectors 110 are embedded in the first portion 108A of the bonding layer 108 in the bottom-up view with sidewalls in contact with the first portion 108A, some of the die connectors 110 are embedded in the second portion 108B of the bonding layer 108 in the bottom-up view with sidewalls in contact with the second portion 108B, and some of the die connectors 110 are disposed along a border between the first portion 108A and the second portion 108B in the bottom-up view with sidewalls in contact with the first portion 108A and the second portion 108B. In the embodiments shown in FIG. 1B, the die connectors 110 have shapes of circles with a diameter D1 in a range from about 5 μm to about 10 μm. The quantity, locations, shapes, and sizes of the die connectors 110 shown in FIGS. 1A and 1B are provided as an example. In other embodiments, the die connectors 110 have other quantities, locations, shapes, and/or sizes.

FIGS. 1C to 1F illustrate embodiments of the upper integrated circuit die 100 similar to the ones shown in FIG. 1B, wherein like numerals refer to like features formed by like processes. The die connectors 110 are omitted in FIGS. 1C to 1F for illustrative purposes. In the embodiments shown in FIG. 1C, the first portions 108A and the second portions 108B of the bonding layer 108 may be arranged in a check pattern of alternating first portions 108A and second portions 108B. Each first portion 108A may be in a shape of a rectangle adjacent to two or more second portions 108B. Each second portion 108B may be in a shape of a rectangle adjacent to two or more first portions 108A. The first portions 108A may have a width W3 in a range from about 20 μm to about 100 μm and a length L3 in a range from about 20 μm to about 100 μm. The second portions 108B may have a width W4 in a range from about 20 μm to about 100 μm and a length L4 in a range from about 20 μm to about 100 μm. In some embodiments, the width W3 equals to the width W4 and the length L3 equals to the length L4. In some embodiments, the width W3, the width W4, the length L3, and the length L4 are equal.

In the embodiments shown in FIG. 1D, the first portions 108A of the bonding layer 108 may be arranged in a staggered array pattern embedded in the second portion 108B of the bonding layer 108. Each first portion 108A may be in a shape of a circle, an oval, or a polygon. In the embodiments where each first portion 108A is a circle, the first portions 108A have a diameter D2 in a range from about 20 μm to about 100 μm and a spacing S2 between two neighboring first portions 108A is in a range from about 20 μm to about 100 μm. In the embodiments shown in FIG. 1E, the first portions 108A of the bonding layer 108 may be arranged in a square array pattern embedded in the second portion 108B of the bonding layer 108. Each first portion 108A may be in a shape of a circle, an oval, or a polygon. In the embodiments where each first portion 108A is a circle, the first portions 108A have a diameter D3 in a range from about 20 μm to about 100 μm and a spacing S3 between two neighboring first portions 108A is in a range from about 20 μm to about 100 μm.

In the embodiments shown in FIG. 1F, the bonding layer 108 comprises heterogeneous regions at corners of the upper integrated circuit die 100 and a homogeneous region among the heterogeneous regions. The heterogeneous regions of the bonding layer 108 are encircled in dash lines for illustrative purposes. The heterogeneous regions may comprise the first portions 108A and the second portions 108B of the bonding layer 108. The homogeneous region may comprise the material of the second portions 108B. Each heterogeneous region may be in shape of a rectangle with a width W5 in a range from about 60 μm to about 6000 μm and a length L5 in a range from about 60 μm to about 6000 μm. The first portions 108A and the second portions 108B in the heterogeneous regions may be arranged in grating patterns of alternating first portions 108A and second portions 108B similar to the embodiments shown in FIG. 1B. The first portions 108A may have a width W6 in a range from about 20 μm to about 100 μm and the second portions 108B may have a width W7 in a range from about 20 μm to about 100 μm. In some embodiments, the width W6 equals to the width W7. The first portions 108A and the second portions 108B in the heterogeneous regions may be arranged in other patterns in accordance with some embodiments, such as the ones shown in FIGS. 1C to 1E. The homogeneous region may be in a shape of a cross extending from a first edge of the upper integrated circuit die 100 to a second edge of the upper integrated circuit die 100 opposite to the first edge and from a third edge of the upper integrated circuit die 100 to a fourth edge of the upper integrated circuit die 100 opposite to the third edge.

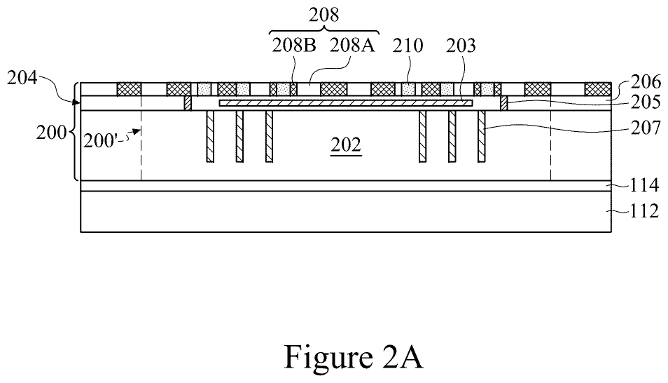

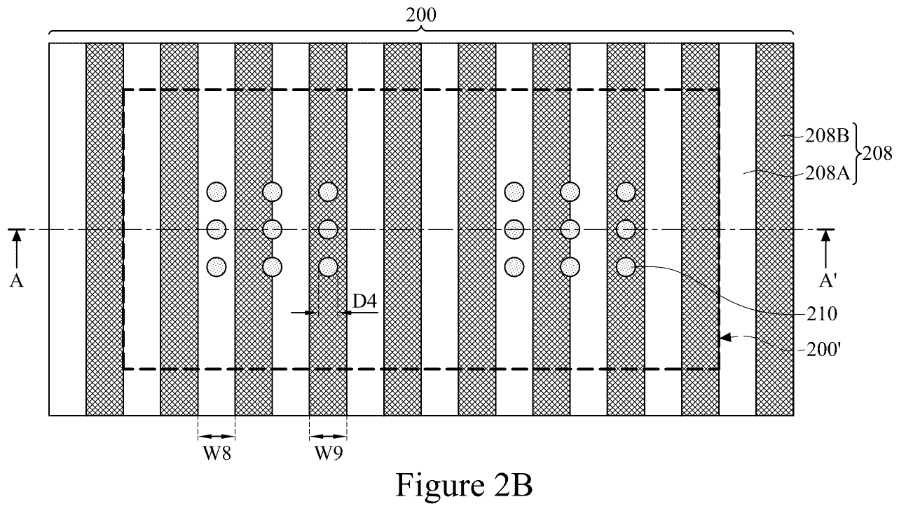

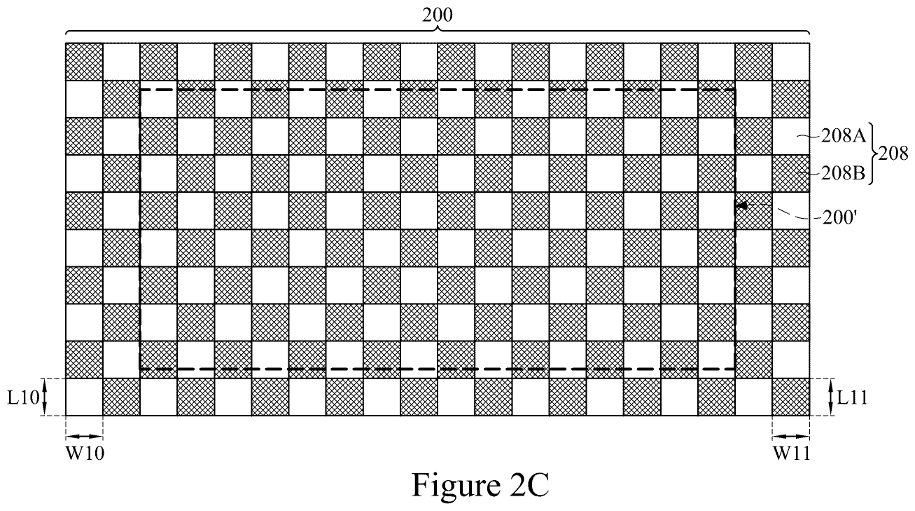

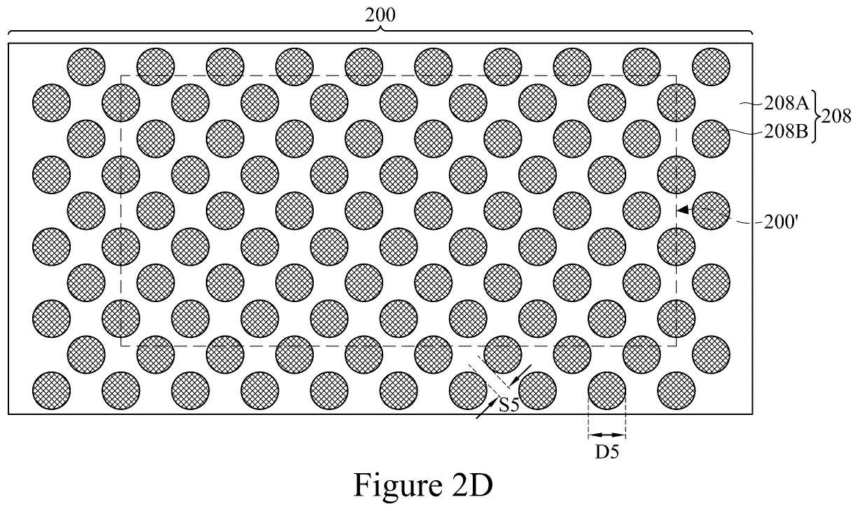

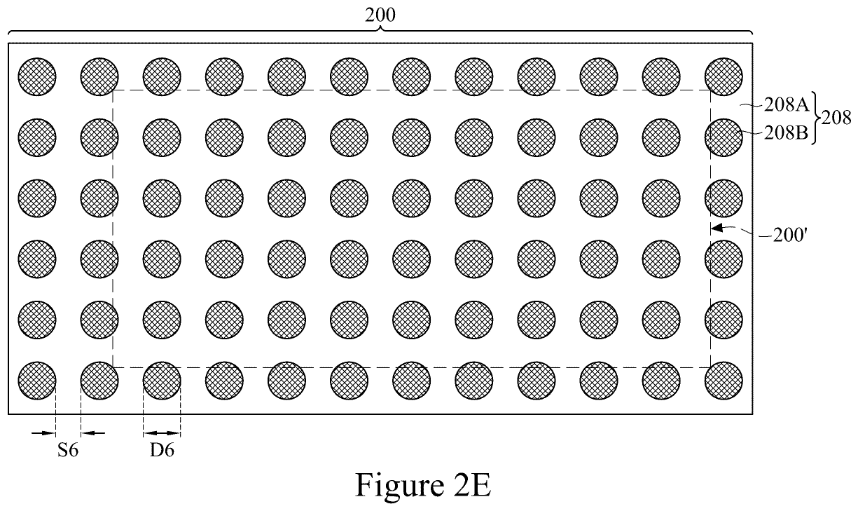

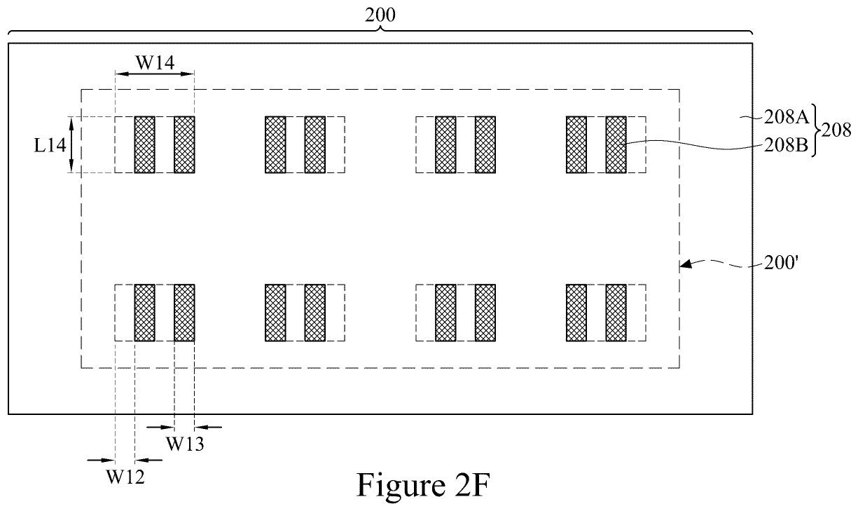

FIGS. 2A-10 illustrate intermediate processing steps in forming an integrated circuit package, in accordance with some embodiments. In FIGS. 2A and 2B, a wafer structure 200 is attached to a carrier 112 by an adhesive 114. The cross-sectional view shown in FIG. 2A may be obtained along reference cross-section A-A′ in the top-down view shown in FIG. 2B. The wafer structure 200 may be subsequently singulated into to one or more lower integrated circuit dies 200′. Sidewalls (e.g., borders) of the projected lower integrated circuit die 200′ are shown dash lines in FIGS. 2A and 2B for illustrative purposes. The carrier 112 may be a semiconductor carrier, a glass carrier, a ceramic carrier, or the like. The carrier 112 may be a wafer. In some embodiments, the adhesive 114 is a thermal-release layer, such as an epoxy-based light-to-heat-conversion (LTHC) release material, which loses its adhesive property when heated. In some embodiments, the adhesive 114 is a UV glue, which loses its adhesive property when exposed to UV light.

The projected lower integrated circuit die 200′ may be a logic die (e.g., CPU, GPU, SoC, AP, microcontroller, etc.), a memory die (e.g., DRAM die, SRAM die, etc.), a power management die (e.g., PMIC die), a RF die, a sensor die, a MEMS die, a signal processing die (e.g., DSP die), a front-end die (e.g., AFE die), the like, or combinations thereof. The materials and manufacturing processes of the features in the projected lower integrated circuit dies 200′ may be found by referring to the like features in the upper integrated circuit die 100. The projected lower integrated circuit die 200′ may include a semiconductor substrate 202, which may have an active surface (e.g., the surface facing upwards in FIG. 2A), which may be called a front side, and an inactive surface (e.g., the surface facing downwards in FIG. 2A), which may be called a back side. The back side of the semiconductor substrate 202 may also be referred to as a back side of the projected lower integrated circuit die 200′ and the front side of the semiconductor substrate 202 may face a front side of the projected lower integrated circuit die 200′.

Devices (not separately illustrated) may be disposed at the active surface of the semiconductor substrate 202. The devices may be active devices (e.g., transistors, diodes, etc.), capacitors, resistors, or the like. The devices may generate a large amount of heat during operation. An interconnect structure 204 may be disposed on the active surface of the semiconductor substrate 202. The interconnect structure 204 may interconnect the devices to form an integrated circuit of projected lower integrated circuit die 200′. The interconnect structure 204 may comprise metallization patterns 203 in dielectric layers 206. The metallization patterns 203 may be electrically coupled to the devices. The interconnect structure 204 may further comprise a seal ring 205 in the dielectric layers 206. In some embodiments, the seal ring 205 extend through the dielectric layers 206. The seal ring 205 may encircle the metallization patterns 203 in the top-down view and a region between the seal ring 205 and sidewalls of the interconnect structure 204 may be referred to as a KOZ of the interconnect structure 204. The KOZ may be free of the metallization patterns 203. The seal ring 205 may be formed of the same or similar material and by the same or similar process as the metallization patterns 203. The seal ring 205 may be electrically isolated from the integrated circuit of the projected lower integrated circuit die 200′. Conductive vias 207 may be disposed in the semiconductor substrate 202. The conductive vias 207 may be electrically coupled to the metallization patterns 203 of the interconnect structure 204. The semiconductor substrate 202 may be thinned in a subsequent process to expose the conductive vias 207 at the inactive surface of the semiconductor substrate 202. After the thinning process, the conductive vias 207 may be referred to as through-substrate vias (TSV).

A bonding layer 208 may be disposed on the interconnect structure 204 at the front side of the projected lower integrated circuit die 200′. The bonding layer 208 may be a heterogeneous bonding layer. The bonding layer 208 may comprise first portions 208A and second portions 208B arranged in an alternating pattern similar to the bonding layer 108 described above with respect to FIGS. 1A and 1B. A surface of the bonding layer 208 may comprise surfaces of the first portions 208A and surfaces of the second portions 208B. Each first portion 208A may be disposed beside one or more second portions 208B, wherein sidewalls of each first portion 208A may be in contact with sidewalls of the neighboring second portion(s) 208B. The first portions 208A and second portions 208B may comprise different materials, which may be selected from silicon oxide (e.g., a tetraethyl orthosilicate (TEOS) based silicon oxide), un-doped silicate glass (USG), silicon nitride, silicon oxynitride, or the like. The bonding layer 208 may be used for bonding with the bonding layer(s) 108 of one or more upper integrated circuit dies 100 in a subsequent process. The patterns and compositions of the first portions 208A and the second portions 208B may lead to a reduced the bonding speed between the upper integrated circuit dies 100 and the projected lower integrated circuit die 200′, which may lead to an improved bonding interface between the upper integrated circuit die 100 and the projected lower integrated circuit die 200′, as discussed in greater details below.

The bonding layer 208 may be formed by a same or similar process described above with respect to the bonding layer 108. In some embodiments, the first portions 208A and the second portions 208B are in contact with the interconnect structure 204. As shown in FIG. 2B, the first portions 208A and the second portions 208B of the bonding layer 208 may be arranged in a grating pattern of alternating first portions 208A and second portions 208B similar to the bonding layer 108 of the embodiments of the upper integrated circuit die 100 shown in FIG. 1B. The embodiments of the upper integrated circuit die 100 shown in FIG. 1B may be used to bond with the embodiments of the projected lower integrated circuit die 200′ shown in FIG. 2B in a subsequent process. Each first portion 208A and each and second portion 208B may be in a shape of a strip extending from one edge of the projected lower integrated circuit die 200′ to an opposing edge of the projected lower integrated circuit die 200′. The first portions 208A may have a width W8 in a range from about 20 μm to about 100 μm and the second portions 208B may have a width W9 in a range from about 20 m to about 100 μm. In some embodiments, the width W8 equals to the width W9. In some embodiments, the width W8 equals to the width W2 and the width W9 equals to the width W1.

Die connector 210 may be disposed in the bonding layer 208. The die connector 210 may be also referred to as bonding pads and may be used for bonding with other integrated circuit dies in a subsequent process. The die connector 210 may be electrically coupled with the metallization patterns 203 and the integrated circuit of the projected lower integrated circuit die 200′. The die connector 210 may be formed by one or more damascene processes, such as single damascene processes, dual damascene processes, or the like. The die connectors 210 may be formed of a suitable conductive material, such as copper, aluminum, or the like. In some embodiments, the die connectors 210 and the die connectors 110 are formed of a same material.

In the embodiments shown in FIGS. 2A and 2B, some of the die connectors 210 are embedded in the first portions 208A of the bonding layer 208 in the top-down view with sidewalls in contact with the first portion 208A, some of the die connectors 210 are embedded in the second portions 208B of the bonding layer 208 in the top-down view with sidewalls in contact with the second portion 208B, and some of the die connectors 210 are disposed along borders between the first portions 208A and the second portions 208B in the top-down view with sidewalls in contact with the first portions 208A and the second portions 208B. In the embodiments shown in FIG. 2B, the die connectors 210 have shapes of circles with a diameter D4 in a range from about 5 μm to about 10 μm. In some embodiments, the diameter D1 of the die connectors 110 equal the diameter D4 of the die connectors 210. The quantity, locations, shapes, and sizes of the die connectors 210 shown in FIGS. 2A and 2B are provided as an example. In other embodiments, the die connectors 210 have other quantities, locations, shapes, and/or sizes.

FIGS. 2C to 2F illustrate embodiments of the projected lower integrated circuit die 200′ similar to the ones shown in FIG. 2B, wherein like numerals refer to like features formed by like processes. The die connectors 210 are omitted in FIGS. 2C to 2F for illustrative purposes. The sidewalls (e.g., borders) of the projected lower integrated circuit die 200′ are shown dash lines in FIGS. 2C to 2F for illustrative purposes.

In the embodiments shown in FIG. 2C, the first portions 208A and the second portions 208B of the bonding layer 208 may be arranged in a check pattern of alternating first portions 208A and second portions 208B similar to the bonding layer 108 of the embodiments of the upper integrated circuit die 100 shown in FIG. 1C. The embodiments of the upper integrated circuit die 100 shown in FIG. 1C may be used to bond with the embodiments of the projected lower integrated circuit die 200′ shown in FIG. 2C in a subsequent process. Each first portion 208A may be in a shape of a rectangle adjacent to two or more second portions 208B. Each second portion 208B may be in a shape of a rectangle adjacent to two or more first portions 208A. The first portions 208A may have a width W10 in a range from about 20 μm to about 100 μm and a length L10 in a range from about 20 μm to about 100 μm. The second portions 208B may have a width W11 in a range from about 20 μm to about 100 μm and a length L11 in a range from about 20 μm to about 100 μm. In some embodiments, the width W10 equals to the width W11 and the length L10 equals to the length L11. In some embodiments, the width W10, the width W11, the length L10, and the length L11 are equal. In some embodiments, the width W10 equals to the width W4, the length L10 equals to the length L4, the width W11 equals to the width W3, and the length L11 equals to the length L3.

In the embodiments shown in FIG. 2D, the first portions 208A of the bonding layer 208 may be arranged in a staggered array pattern embedded in the second portion 208B of the bonding layer 208 similar to the bonding layer 108 of the embodiments of the upper integrated circuit die 100 shown in FIG. 1D. The embodiments of the upper integrated circuit die 100 shown in FIG. 1D may be used to bond with the embodiments of the projected lower integrated circuit die 200′ shown in FIG. 2D in a subsequent process. Each first portion 208A may be in a shape of a circle, an oval, or a polygon. In the embodiments where each first portion 208A is a circle, the first portions 208A have a diameter D5 in a range from about 20 m to about 100 μm and a spacing S5 between two neighboring first portions 208A is in a range from about 20 μm to about 100 μm. In some embodiments, the diameter D5 equals to the diameter D2 and the spacing S5 equals to the spacing S2.

In the embodiments shown in FIG. 2E, the first portions 208A of the bonding layer 208 may be arranged in a square array pattern embedded in the second portion 208B of the bonding layer 208 similar to the bonding layer 108 of the embodiments of the upper integrated circuit die 100 shown in FIG. 1E. The embodiments of the upper integrated circuit die 100 shown in FIG. 1E may be used to bond with the embodiments of the projected lower integrated circuit die 200′ shown in FIG. 2E in a subsequent process. Each first portion 208A may be in a shape of a circle, an oval, or a polygon. In the embodiments where each first portion 208A is a circle, the first portions 208A have a diameter D6 in a range from about 20 m to about 100 μm and a spacing S6 between two neighboring first portions 208A is in a range from about 20 μm to about 100 μm. In some embodiments, the diameter D6 equals to the diameter D3 and the spacing S6 equals to the spacing S3.

In the embodiments shown in FIG. 2F, the bonding layer 208 comprises heterogeneous regions and a homogeneous region surrounding the heterogeneous regions similar to the bonding layer 108 of the embodiments of the upper integrated circuit die 100 shown in FIG. 1F. The heterogeneous regions of the bonding layer 208 are encircled in dash lines for illustrative purposes. The embodiments of the upper integrated circuit die 100 shown in FIG. 1F may be used to bond with the embodiments of the projected lower integrated circuit die 200′ shown in FIG. 2F in a subsequent process, wherein the heterogeneous regions of the upper integrated circuit die 100 and the projected lower integrated circuit die 200′ may be bonded together and the homogeneous regions of the upper integrated circuit die 100 and the projected lower integrated circuit die 200′ may be bonded together.

The heterogeneous regions may comprise the first portions 208A and the second portions 208B of the bonding layer 208. The homogeneous region may comprise the material of the first portions 208A. Each heterogeneous region may be in shape of a rectangle with a width W14 in a range from about 60 μm to about 6000 μm and a length L14 in a range from about 60 μm to about 6000 μm. In some embodiments, the width W14 equals to the width W5 and the length L14 equals to the length L5. The first portions 208A and the second portions 208B in the heterogeneous regions may be arranged in grating patterns of alternating first portions 208A and second portions 208B similar to the embodiments shown in FIG. 2B. The first portions 208A may have a width W12 in a range from about 20 μm to about 100 μm and the second portions 208B may have a width W13 in a range from about 20 m to about 100 μm. In some embodiments, the width W12 equals to the width W13. In some embodiments, the width W12 equals to the width W7 and the width W13 equals to the width W6. The first portions 208A and the second portions 208B in the heterogeneous regions may be arranged in other patterns in accordance with some embodiments, such as the ones shown in FIGS. 2C to 2E. The homogeneous region may extend from a first edge of the projected lower integrated circuit die 200′ to a second edge of the projected lower integrated circuit die 200′ opposite to the first edge and from a third edge of the projected lower integrated circuit die 200′ to a fourth edge of the projected lower integrated circuit die 200′ opposite to the third edge.

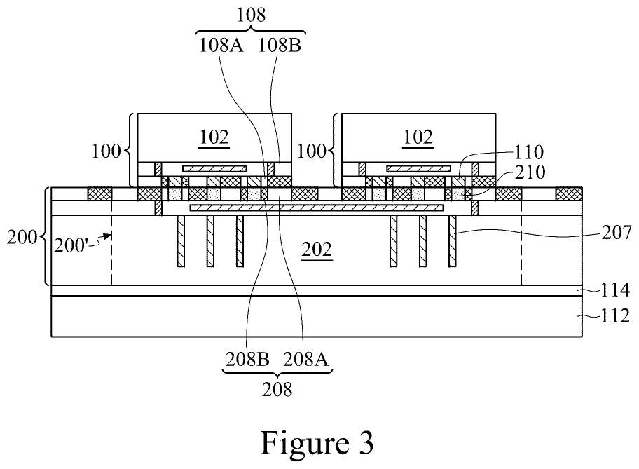

In FIG. 3, the upper integrated circuit dies 100 are bonded to the wafer structure 200. Sidewalls (e.g., borders) of the projected lower integrated circuit die 200′ are shown dash lines in FIG. 3 for illustrative purposes. FIG. 3 shows a layout of two the upper integrated circuit dies 100 on the projected lower integrated circuit die 200′ as an example. Other numbers (e.g., three, four) of the upper integrated circuit dies 100 with other layouts on the projected lower integrated circuit die 200′ are contemplated. The upper integrated circuit dies 100 may be bonded to the projected lower integrated circuit die 200′ in the wafer structure 200 by bonding the bonding layers 108 of the upper integrated circuit dies 100 to the bonding layer 208 of the projected lower integrated circuit die 200′ as well as bonding the die connectors 110 of the upper integrated circuit dies 100 to the corresponding die connector 210 of the projected lower integrated circuit die 200′. The bonding between the bonding layers 108 and the bonding layer 208 may be direct dielectric-to-dielectric bonding. The bonding between the die connectors 110 and the die connector 210 may be direct metal-to-metal bonding.

The first portions 108A of the bonding layers 108 may be bonded to the corresponding second portions 208B of the bonding layer 208 by direct dielectric-to-dielectric bonding and the second portions 108B of the bonding layers 108 may be bonded to the corresponding first portions 208A of the bonding layers 208 by direct dielectric-to-dielectric bonding. The first portions 108A and the second portions 208B may comprise different materials, and the second portions 108B and the first portions 208A may comprise different materials. The bonding configuration between the bonding layers 108 and the bonding layer 208 described above may lead to a reduced the bonding speed during the bonding process between the upper integrated circuit dies 100 and the projected lower integrated circuit die 200′, which may reduce or prevent the risk of forming bulges and/or air gaps between the upper integrated circuit dies 100 and the projected lower integrated circuit die 200′. As a result, an improved bonding interface between the upper integrated circuit die 100 and the projected lower integrated circuit die 200′ may be obtained. In some embodiments, the first portions 108A and the first portions 208A may comprise a same material, and the second portions 108B and the second portions 208B may comprise a same material.

The bonding process may include a surface treatment step, a pressing step, and an annealing step. During the surface treatment step, surfaces of the bonding layers 108 and the die connectors 110 of the upper integrated circuit dies 100 as well as surfaces of the bonding layer 208 and the die connector 210 of the wafer structure 200 may be cleaned and treated with plasma or the like. Then, the upper integrated circuit dies 100 may be placed on the projected lower integrated circuit die 200′ in the wafer structure 200. A small pressing force may be applied to press the upper integrated circuit dies 100 against the wafer structure 200 during the press step at a low temperature, such as room temperature. After the pressing step, dielectric-to-dielectric bonds may be formed between the bonding layers 108 and the bonding layer 208. The bonding strength between the bonding layers 108 and the bonding layer 208 may be improved in the subsequent annealing step at a higher temperature. Further, during the annealing step, the material of the die connectors 110 may intermingle and bond with the material of the die connector 210, so that metal-to-metal bonds may be formed. In some embodiments, after the bonding process, sidewalls of the die connectors 110 are aligned or coterminous with sidewalls of the corresponding die connectors 210, sidewalls of the first portions 108A are aligned or coterminous with sidewalls of the corresponding second portions 208B, and sidewalls of second portions 108B are aligned or coterminous with sidewalls of the corresponding first portions 208A.

The above description with respect to FIG. 3 uses a front-to-front package configuration in accordance with some embodiments, wherein the front sides of the upper integrated circuit dies 100 may face the front side of the projected lower integrated circuit die 200′ after bonding. In other embodiments, other package configurations may be used, such as a front-to-back bonding configuration, wherein the front sides of upper integrated circuit dies 100 may face the back side of the projected lower integrated circuit die 200′ or the back sides of upper integrated circuit dies 100 may face the front side of the projected lower integrated circuit die 200′.

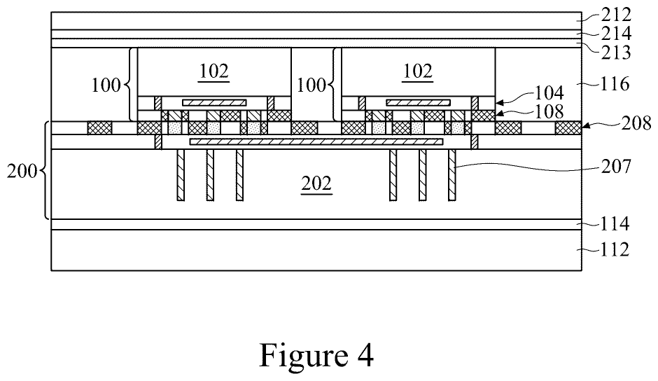

In FIG. 4, a gap-fill layer 116 is formed around the upper integrated circuit dies 100 and a carrier 212 is bonded to surfaces of the semiconductor substrates 102 and the gap-fill layer 116. The gap-fill layer 116 may encircle the upper integrated circuit dies 100 in the top-down view. The gap-fill layer 116 may extend along sidewalls of the upper integrated circuit dies 100 (e.g., the semiconductor substrates 102, the interconnect structure 104, and the bonding layer 108). The gap-fill layer 116 may be an insulating layer and may be formed of a dielectric material, such as silicon oxide, PSG, BSG, BPSG, a TEOS based oxide, or the like, which may be formed by a suitable deposition process such as CVD, ALD, or the like. Initially, the gap-fill layer 116 may cover the surfaces the semiconductor substrates 102. A thinning process may be performed to level the surfaces of the gap-fill layer 116 the surfaces the semiconductor substrates 102. The thinning process may be a CMP process, a grinding process, an etch-back process, combinations thereof, or the like. After the thinning process, the surfaces of the semiconductor substrates 102 and the gap-fill layer 116 may be substantially coplanar (within process variations).

The carrier 212 may be a semiconductor carrier, a glass carrier, a ceramic carrier, or the like. The carrier 212 may be a wafer having the same or similar size as the carrier 112. In some embodiments, the carrier 212 is bonded to the semiconductor substrates 102 and the gap-fill layer 116 using bonding layers 213 and 214. The bonding layer 213 may be formed on the semiconductor substrates 102 and the gap-fill layer 116, and the bonding layer 214 may be formed on the carrier 212. The bonding layer 213 and the bonding layer 214 may each comprise a dielectric material, such as silicon dioxide or the like, and may be formed by a suitable deposition process such as CVD, ALD, or the like. The structure over the carrier 112 may be bonded to the carrier 212 by bonding the bonding layer 213 and the bonding layer 214 by the same or similar process used for bonding the bonding layer 108 and the bonding layer 208 described with respect to FIG. 3.

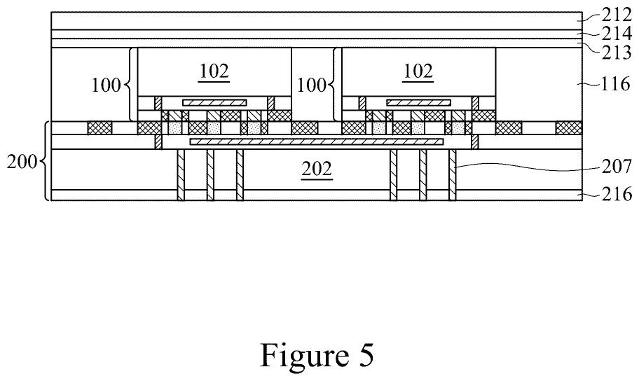

In FIG. 5, the carrier 112 and the adhesive 114 are removed, the semiconductor substrate 202 of the wafer structure 200 is thinned to expose the conductive vias 207, and a dielectric layer 216 is formed on the inactive surface of the semiconductor substrate 202. The removal process of the carrier 112 and the adhesive 114 may include projecting a light beam such as a laser beam or a UV light beam on the adhesive 114 so that the adhesive 114 decomposes upon exposure to the light beam. Then the carrier 112 may be removed. The thinning process of the semiconductor substrate 202 may be a CMP process, a grinding process, an etch-back process, combinations thereof, or the like. After the thinning process portions of the conductive vias 207 may protrude from the inactive surface of the semiconductor substrate 202.

Then the dielectric layer 216 may be deposited to cover the exposed sidewalls of the conductive vias 207. In some embodiments, the dielectric layer 216 comprises polybenzoxazole (PBO), polyimide, a benzocyclobutene (BCB) based polymer, or the like, and is formed by a suitable coating process such as spin coating, lamination, or the like. In some embodiments, the dielectric layer 216 comprises silicon dioxide, silicon nitride, silicon oxynitride, or the like, and is formed by a suitable deposition process such as CVD, ALD, or the like. Initially, the dielectric layer 216 may cover the bottom surfaces the conductive vias 207. Another thinning process may be performed to level the bottom surfaces of the dielectric layer 216 and the conductive vias 207. The thinning process may be a CMP process, a grinding process, an etch-back process, combinations thereof, or the like. After the thinning process, the bottom surfaces of the dielectric layer 216 and the conductive vias 207 may be substantially coplanar (within process variations).

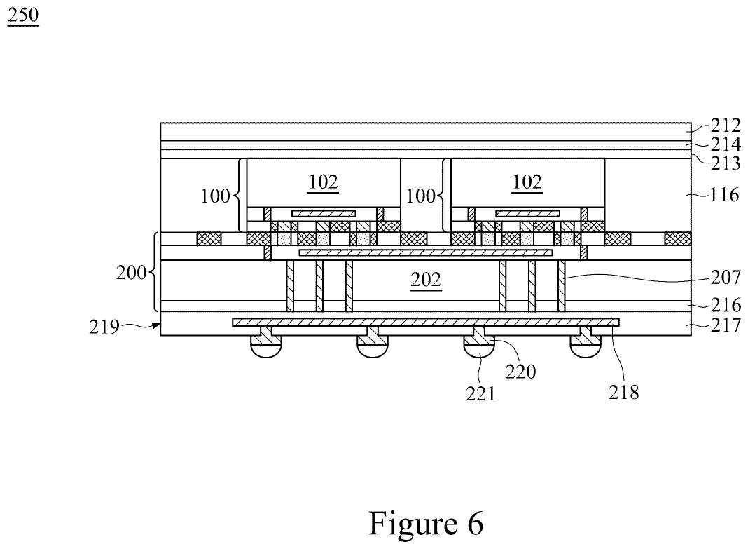

In FIG. 6, a redistribution structure 219 is formed on the bottom surfaces of the dielectric layer 216 and the conductive vias 207, and under-bump metallizations (UBMs) 220 and electrical connectors 221 are formed on the redistribution structure 219. The structure shown in FIG. 6 may be referred to as a wafer structure 250. The redistribution structure 219 may include dielectric layers 217 and metallization patterns 218 in the dielectric layers 217. The dielectric layers 217 may be low-k dielectric layers comprising a suitable dielectric material, such as PBO, polyimide, a BCB-based polymer, silicon dioxide, silicon nitride, silicon oxynitride, or the like. The dielectric layers 217 may be formed by spin coating, lamination, CVD, ALD, or the like. The metallization patterns 218 may include metal lines and vias, which may be formed in the dielectric layers 217 by damascene processes, such as single damascene processes, dual damascene processes, or the like. The metallization patterns 218 may be formed of a suitable conductive material, such as copper, tungsten, aluminum, silver, gold, a combination thereof, or the like. The metallization patterns 218 may be electrically coupled to the conductive vias 207. The UBMs 220 may have portions extending along a bottom surface of the dielectric layers 217 and portions extending through the dielectric layers 217 to electrically couple to the metallization patterns 218.

As an example to form the UBMs 220, portions of the dielectric layers 217 (specifically, at least the bottom layer of the dielectric layers 217) may be patterned to form openings exposing portions of the metallization patterns 218. The patterning may be done by an acceptable photolithography process, such as forming a mask then performing an anisotropic etching. The mask may be removed after the patterning. A seed layer may be formed on the dielectric layers 217, in the openings through the dielectric layers 217, and on the exposed portions of the metallization patterns 218. The seed layer may be a metal layer, which may be a single layer or a composite layer comprising a plurality of sub-layers formed of different materials. The seed layer may be formed using a suitable deposition process, such as physical vapor deposition (PVD) or the like. A photoresist may be then formed and patterned on the seed layer. The patterning may form openings through the photoresist to expose the seed layer. The pattern of the photoresist may correspond to the shapes, sizes, and locations of the UBMs 220. A conductive material may be formed in the openings of the photoresist and on the exposed portions of the seed layer. The conductive material may be formed by plating, such as electroless plating, electroplating, or the like. The conductive material may comprise a metal or a metal alloy, such as copper, titanium, tungsten, aluminum, the like, or combinations thereof. Then the photoresist and portions of the seed layer on which the conductive material is not formed may be removed. The remaining portions of the seed layer and conductive material may form the UBMs 220.

Electrical connectors 221 may be formed on the UBMs 220. The electrical connectors 221 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the electrical connectors 221 comprise a conductive material such as solder, copper, aluminum, gold, nickel, silver, palladium, tin, the like, or a combination thereof. The electrical connectors 221 may be formed by initially forming a layer of solder through evaporation, electroplating, printing, solder transfer, ball placement, or the like. Once the layer of solder has been formed on the structure, a reflow may be performed to shape the solder into the desired bump shapes. In some embodiments, the electrical connectors 221 comprise metal pillars, such as a copper pillar, formed by a sputtering, printing, electroplating, electroless plating, CVD, or the like, which are solder free and have substantially vertical sidewalls. A metal cap layer may be formed on top of the metal pillars by a plating process.

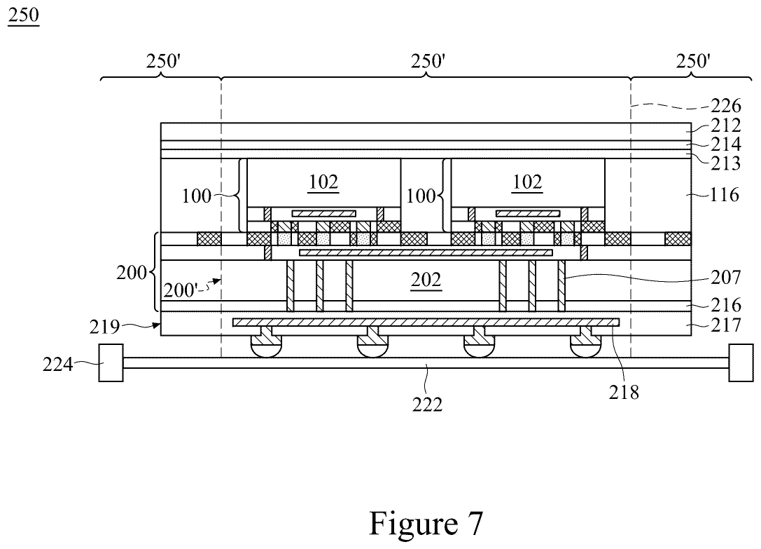

In FIG. 7, the wafer structure 250 is singulated into individual integrated circuit package components 250′. As the same time, wafer structure 200 is singulated into individual lower integrated circuit die 200′. The processes discussed above may be performed using wafer-level processing. The carrier 212 may be a wafer and may include many structures (not separately illustrated) similar to the one illustrated in FIG. 7. The wafer structure 250 may be placed on a tape 222 supported by a frame 224. The wafer structure 250 may be then singulated along scribe lines 226, so that the wafer structure 250 may be separated into individual integrated circuit package components 250′. The singulation process may include a sawing process, a laser cutting process, or the like. A cleaning process or rinsing process may be performed after the singulation process.

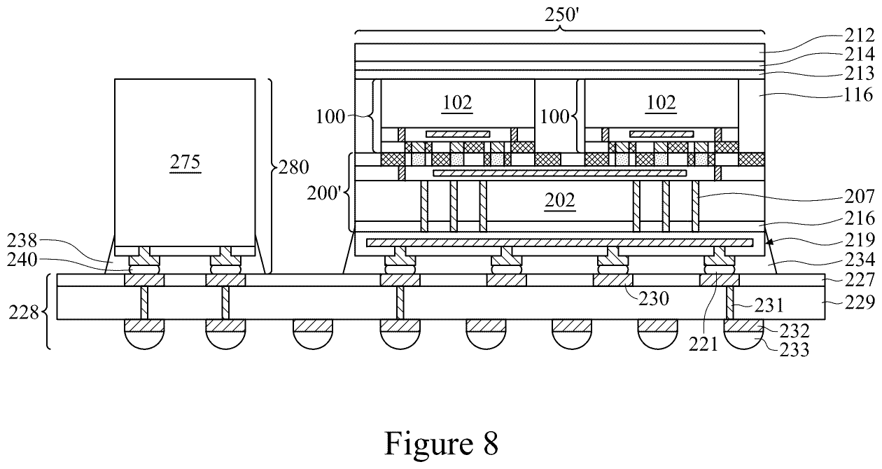

In FIG. 8, the integrated circuit package component 250′ is bonded to an integrated circuit package component 228 and an underfill 234 is formed between the integrated circuit package component 250′ and the integrated circuit package component 228. Further, an integrated circuit package component 280 is bonded to the integrated circuit package component 228 beside the integrated circuit package component 250′ and an underfill 238 is formed between the integrated circuit package component 280 and the integrated circuit package component 228.

The semiconductor package component 228 may comprise a substrate 229, dielectric layers 227 on a first side of the substrate 229, conductive features 230 in the dielectric layers 227, and conductive features 232 on a second side of the substrate 229. The conductive features 230 may comprise conductive lines and conductive vias. The conductive features 232 may comprise UBMs. Conductive vias 231 may extend through the substrate 229 and may electrically couple the conductive features 230 to the conductive features 232. Electrical connectors 233 may be on the conductive features 232 and may be used to bond to an external device, such as package substrate, printed circuit board (PCB), or the like. The semiconductor package component 228 may be referred to as an interposer.

During the bonding process between the integrated circuit package component 250′ and the integrated circuit package component 228, the electrical connectors 221 may be reflowed to bond the integrated circuit package component 250′ to exposed portions of the conductive features 230. The electrical connectors 221 may electrically couple the integrated circuit package component 228 to the integrated circuit package component 250′. The underfill 234 may surround the electrical connectors 221 and protect the joints resulting from the reflowing of the electrical connectors 221. The underfill 234 may encircle the integrated circuit package component 250′ in the top-down view. The underfill 234 may be formed by a capillary flow process after the integrated circuit package component 250′ is attached or by a suitable deposition method before the integrated circuit package component 250′ is bonded. The underfill 234 may be subsequently cured.

The integrated circuit package component 280 may comprise one or more integrated circuit dies in an active region 275 of the integrated circuit package component 280. In some embodiments, the active region 275 comprises a stack of interconnected memory dies and the integrated circuit package component 280 is referred to as a high bandwidth memory (HBM) device. The electrical connectors 240 of the integrated circuit package component 280 may electrically couple the integrated circuit package component 228 to the integrated circuit package component 280. The electrical connectors 240 may be formed of the same or similar material and by the same or similar process as the electrical connectors 221. The underfill 238 may surround the electrical connectors 240 and may encircle the integrated circuit package component 280 in the top-down view. The underfill 238 may be formed of the same or similar material and by the same or similar process as the underfill 234.

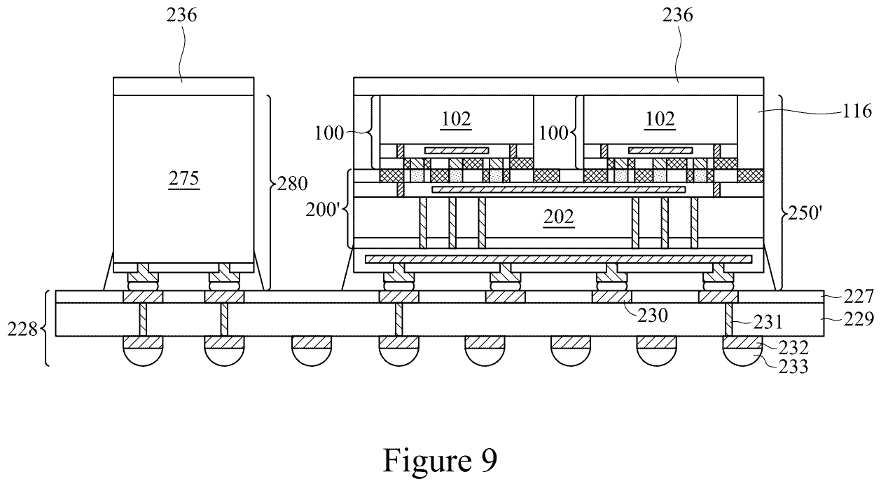

In FIG. 9, the carrier 212, the bonding layer 213, and the bonding layer 214 are removed from the integrated circuit package component 250′, and adhesive layer 236 is formed on the gap-fill layer 116 and the upper integrated circuit dies 100 of the integrated circuit package component 250′ as well as the active region 275 of the integrated circuit package component 280. The carrier 212, the bonding layer 213, and the bonding layer 214 may be removed by a CMP process, a grinding process, an etch-back process, combinations thereof, or the like. The adhesive layer 236 may comprise a thermal interface material (TIM), which may be a material with high thermal conductivity, such as, thermal paste, gel-based thermal adhesive, graphite, graphene film, the like, or the combinations thereof.

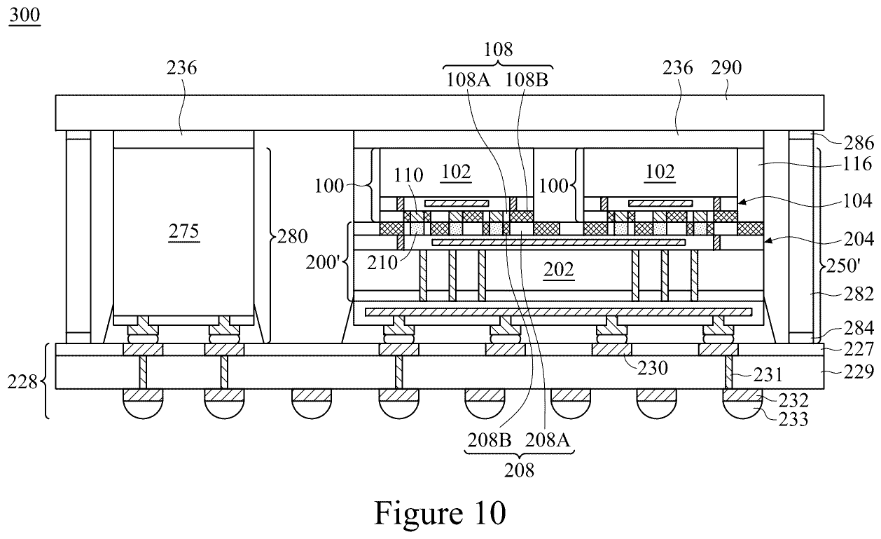

In FIG. 10, a stiffener ring 282 is attached to the integrated circuit package component 228 and a lid 290 is attached to the stiffener ring 282 as well as the integrated circuit package component 250′ and the integrated circuit package component 280. The structure shown in FIG. 10 may be referred to as an integrated circuit package 300. The stiffener ring 282 may be used to provide additional support to the integrated circuit package component 228 during subsequent manufacturing processes to reduce warpage or other types of deformation of the integrated circuit package component 228. The stiffener ring 282 may be formed of a material with a large hardness value, such as a metal, metal alloy, or the like. The stiffener ring 282 may be attached to the integrated circuit package component 228 by an adhesive 284, such as an epoxy, glue, or the like.

The lid 290 may be used to dissipate heat generated by the integrated circuit package component 250′ and the integrated circuit package component 280 during operation of the integrated circuit package 300. The lid 290 may be attached to the integrated circuit package component 250′ and the integrated circuit package component 280 by the adhesive layers 236, and to the stiffener ring 282 by an adhesive 286, such as an epoxy, glue, or the like. The lid 290 may be formed of a metal or a metal alloy, such as copper, stainless steel, or the like. Due to the bonding configuration between the bonding layers 108 of the upper integrated circuit dies 100 and the bonding layer 208 of lower integrated circuit die 200′ described above, the risk of forming bulges and/or air gaps between the upper integrated circuit dies 100 and the lower integrated circuit die 200′ may be reduced or prevented, which may lead to improved bonding interfaces between the upper integrated circuit dies 100 and the lower integrated circuit die 200′. As a result, the heat generated by the lower integrated circuit die 200′ may be more effectively transferred to the lid 290 and dissipated during operation, thereby improving the performance and the reliability of the integrated circuit package 300.

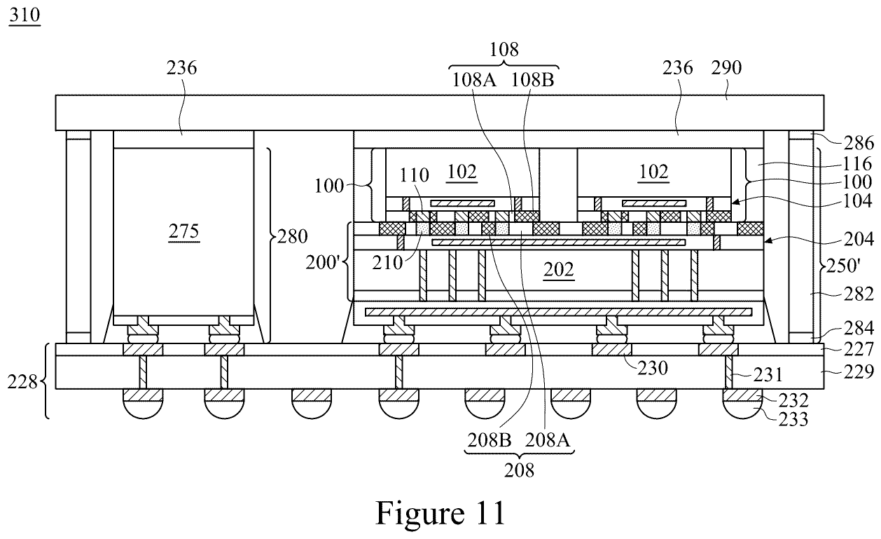

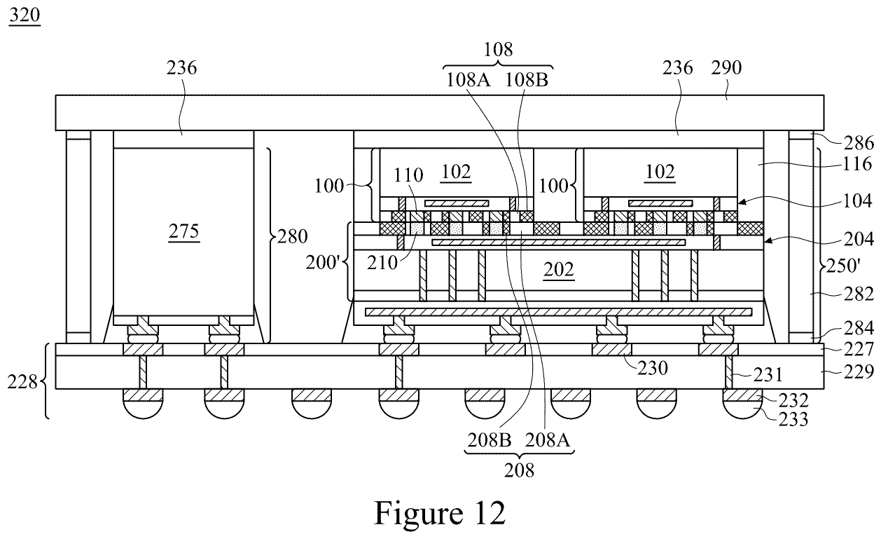

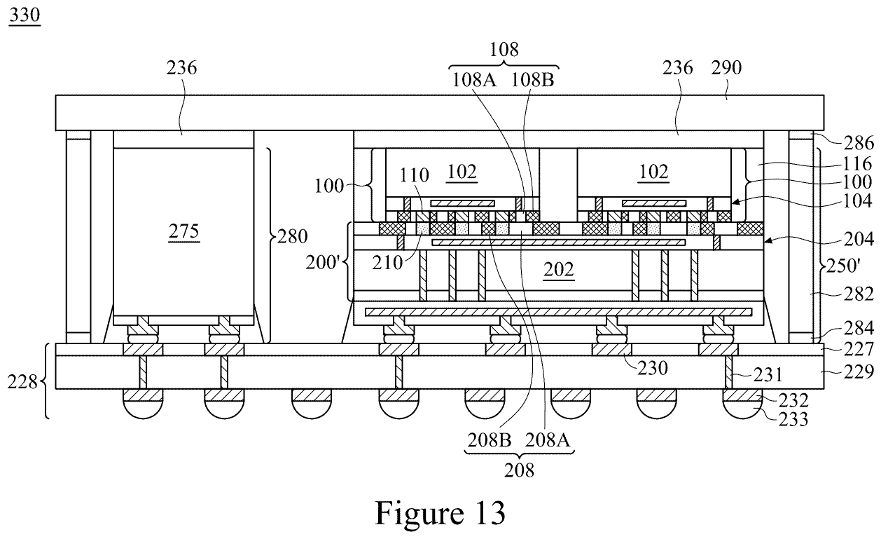

FIGS. 11, 12, and 13 show an integrated circuit package 310, an integrated circuit package 320, and an integrated circuit package 330, respectively, which are similar to the integrated circuit package 300 shown in FIG. 10, wherein like numerals refer to like features formed by like processes. In the integrated circuit packages 310, 320, and 330, at least some of the sidewalls of the first portions 108A of the bonding layer 108 are not aligned or coterminous with the sidewalls of the corresponding second portions 208B, and at least some of the sidewalls of second portions 108B are not aligned or coterminous with the sidewalls of the corresponding first portions 208A. One first portion 208A may be bonded with more than one second portion 108B and one second portion 208B may be bonded with more than one first portion 108A. In some embodiments, one first portion 208A is bonded with one second portion 108B and one first portion 108A. In some embodiments, one second portion 208B is bonded with one second portion 108B and one first portion 108A. In some embodiments, one first portion 208A is bonded with one second portion 108B and two first portions 108A. In some embodiments, one first portion 208A is bonded with two second portions 108B and one first portion 108A. In some embodiments, one second portion 208B is bonded with one second portion 108B and two first portions 108A. In some embodiments, one second portion 208B is bonded with two second portions 108B and one first portion 108A.

The embodiments may have some advantageous features. Due to the bonding configuration between the bonding layers 108 of the upper integrated circuit dies 100 and the bonding layer 208 of lower integrated circuit die 200′, improved bonding interfaces between the upper integrated circuit dies 100 and the lower integrated circuit die 200′ may be obtained. As a result, the heat generated by the lower integrated circuit die 200′ may be more effectively transferred to the lid 290 and dissipated during operation, thereby improving the performance and the reliability of the integrated circuit packages 300, 310, 320, and 330.

In an embodiment, an integrated circuit package includes a first die, including: a first semiconductor substrate; a first bonding layer over the first semiconductor substrate, wherein the first bonding layer includes a first portion including a first material and a second portion including a second material, wherein the first material is different from the second material; and a first die connector in the first bonding layer, wherein a surface of the first bonding layer includes a surface of the first portion, a surface of the second portion, and a surface of the first die connector. In an embodiment, the first bonding layer further includes additional first portions including the first material and additional second portions including the second material, and wherein the first portions and the second portions are arranged in a grating pattern of alternating first portions and second portions in a top-down view. In an embodiment, the first bonding layer further includes additional first portions including the first material and additional second portions including the second material, and wherein the first portions and the second portions are arranged in a check pattern of alternating first portions and second portions in a top-down view. In an embodiment, the first bonding layer further includes additional first portions including the first material, and wherein the first portions are arranged in a staggered array pattern embedded in the second portion in a top-down view. In an embodiment, the first bonding layer further includes additional first portions including the first material, and wherein the first portions are arranged in a square array pattern embedded in the second portion in a top-down view. In an embodiment, the first bonding layer includes a heterogeneous region and a homogeneous region, wherein the heterogeneous region includes the first portion and the second portion, wherein the heterogeneous region is disposed adjacent a corner of the first die, and wherein the homogeneous region includes an additional first portion extending from a first edge of the first die to a second edge of the first die opposite the first edge and from a third edge of the first die to a fourth edge of the first die opposite the third edge. In an embodiment, the integrated circuit package further includes a second die bonded to the first die, wherein the second die includes a second bonding layer and a second die connector in the second bonding layer, wherein the second bonding layer includes a third portion including the first material and a fourth portion including the second material, and wherein a surface of second bonding layer includes a surface of the third portion, a surface of the fourth portion, and a surface of the second die connector. In an embodiment, the surface of the first portion is bonded with the surface of the fourth portion, wherein the surface of the second portion is bonded with the surface of the third portion, and wherein surface of the first die connector is bonded with the surface of the second die connector.

In an embodiment, an integrated circuit package includes a first die, including: a first semiconductor substrate; a first bonding layer over the first semiconductor substrate, wherein the first bonding layer includes a first heterogeneous region, wherein the first heterogeneous region includes a first material and a second material, and wherein the first material is different from the second material; and a first die connector in the first bonding layer, wherein the first die connector includes a third material; and a second die, including: a second semiconductor substrate; a second bonding layer over the second semiconductor substrate, wherein the second bonding layer includes a second heterogeneous region, wherein the second heterogeneous region includes the first material and the second material, wherein the first bonding layer is bonded to the second bonding layer; and a second die connector in the second bonding layer, wherein the second die connector includes the third material, and wherein the first die connector is bonded to the second die connector. In an embodiment, the first material of the first heterogeneous region is bonded with the second material of the second heterogeneous region, and wherein the second material of the first heterogeneous region is bonded with the first material of the second heterogeneous region. In an embodiment, the first bonding layer further includes a first homogeneous region in a shape of a cross, wherein the first homogeneous region includes the first material, wherein the second bonding layer further includes a second homogeneous region in a shape of a cross, wherein the second homogeneous region includes the second material, and wherein the first homogeneous region is bonded to the second homogeneous region. In an embodiment, the first material and second material are dielectric materials, and wherein the third material is a conductive material. In an embodiment, the first material is silicon nitride and the second material is silicon oxide. In an embodiment, first material is undoped silicate glass (USG) and the second material is silicon oxide.

In an embodiment, a method of forming an integrated circuit package includes attaching a first die to a carrier, the first die including: a first semiconductor substrate; a first bonding layer over the first semiconductor substrate, wherein the first bonding layer includes a first portion including a first material and a second portion including a second material, wherein the first material is different from the second material, and wherein a sidewall of the first portion is in contact with a sidewall of the second portion; and a first die connector in the first bonding layer; and bonding a second die to the first die, the second die including: a second semiconductor substrate; a second bonding layer over the second semiconductor substrate, wherein the second bonding layer includes a third portion including the first material and a fourth portion including the second material, and wherein a sidewall of the third portion is in contact with a sidewall of the fourth portion; and a second die connector in the second bonding layer. In an embodiment, the first portion is bonded to the fourth portion by dielectric-to-dielectric bonding, wherein the second portion is bonded to the third portion by dielectric-to-dielectric bonding, and wherein the first die connector is bonded to the second die connector by metal-to-metal bonding. In an embodiment, the first portion is bonded to the third portion by dielectric-to-dielectric bonding. In an embodiment, the second bonding layer includes an additional third portion including the first material, wherein a sidewall of the additional third portion is in contact with another sidewall of the fourth portion, and wherein the first portion is bonded to the additional third portion by dielectric-to-dielectric bonding. In an embodiment, the first material is undoped silicate glass (USG), silicon oxide, silicon nitride, or silicon oxynitride, and wherein the second material is undoped silicate glass (USG), silicon oxide, silicon nitride, or silicon oxynitride. In an embodiment, the first bonding layer further includes additional first portions including the first material and additional second portions including the second material, and wherein the first portions and the second portions are arranged in an alternating pattern in a top-down view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit package, comprising:
a first die, comprising:
a first semiconductor substrate;
a first bonding layer over the first semiconductor substrate, wherein the first bonding layer comprises a first portion comprising a first material and a second portion comprising a second material, wherein the first material is different from the second material; and
a first die connector in the first bonding layer, wherein a surface of the first bonding layer comprises a surface of the first portion, a surface of the second portion, and a surface of the first die connector.

2. The integrated circuit package of claim 1, wherein the first bonding layer further comprises additional first portions comprising the first material and additional second portions comprising the second material, and wherein the first portions and the second portions are arranged in a grating pattern of alternating first portions and second portions in a top-down view.

3. The integrated circuit package of claim 1, wherein the first bonding layer further comprises additional first portions comprising the first material and additional second portions comprising the second material, and wherein the first portions and the second portions are arranged in a check pattern of alternating first portions and second portions in a top-down view.

4. The integrated circuit package of claim 1, wherein the first bonding layer further comprises additional first portions comprising the first material, and wherein the first portions are arranged in a staggered array pattern embedded in the second portion in a top-down view.

5. The integrated circuit package of claim 1, wherein the first bonding layer further comprises additional first portions comprising the first material, and wherein the first portions are arranged in a square array pattern embedded in the second portion in a top-down view.

6. The integrated circuit package of claim 1, wherein the first bonding layer comprises a heterogeneous region and a homogeneous region, wherein the heterogeneous region comprises the first portion and the second portion, wherein the heterogeneous region is disposed adjacent a corner of the first die, and wherein the homogeneous region comprises an additional first portion extending from a first edge of the first die to a second edge of the first die opposite the first edge and from a third edge of the first die to a fourth edge of the first die opposite the third edge.

7. The integrated circuit package of claim 1, further comprising a second die bonded to the first die, wherein the second die comprises a second bonding layer and a second die connector in the second bonding layer, wherein the second bonding layer comprises a third portion comprising the first material and a fourth portion comprising the second material, and wherein a surface of second bonding layer comprises a surface of the third portion, a surface of the fourth portion, and a surface of the second die connector.

8. The integrated circuit package of claim 7, wherein the surface of the first portion is bonded with the surface of the fourth portion, wherein the surface of the second portion is bonded with the surface of the third portion, and wherein surface of the first die connector is bonded with the surface of the second die connector.

9. An integrated circuit package, comprising:
a first die, comprising:
a first semiconductor substrate;
a first bonding layer over the first semiconductor substrate, wherein the first bonding layer comprises a first heterogeneous region, wherein the first heterogeneous region comprises a first material and a second material, and wherein the first material is different from the second material; and
a first die connector in the first bonding layer, wherein the first die connector comprises a third material; and
a second die, comprising:
a second semiconductor substrate;
a second bonding layer over the second semiconductor substrate, wherein the second bonding layer comprises a second heterogeneous region, wherein the second heterogeneous region comprises the first material and the second material, wherein the first bonding layer is bonded to the second bonding layer; and
a second die connector in the second bonding layer, wherein the second die connector comprises the third material, and wherein the first die connector is bonded to the second die connector.

10. The integrated circuit package of claim 9, wherein the first material of the first heterogeneous region is bonded with the second material of the second heterogeneous region, and wherein the second material of the first heterogeneous region is bonded with the first material of the second heterogeneous region.

11. The integrated circuit package of claim 9, wherein the first bonding layer further comprises a first homogeneous region in a shape of a cross, wherein the first homogeneous region comprises the first material, wherein the second bonding layer further comprises a second homogeneous region in a shape of a cross, wherein the second homogeneous region comprises the second material, and wherein the first homogeneous region is bonded to the second homogeneous region.

12. The integrated circuit package of claim 9, wherein the first material and second material are dielectric materials, and wherein the third material is a conductive material.

13. The integrated circuit package of claim 12, wherein the first material is silicon nitride and the second material is silicon oxide.

14. The integrated circuit package of claim 12, wherein the first material is undoped silicate glass (USG) and the second material is silicon oxide.

15. A method of forming an integrated circuit package, the method comprising:
attaching a first die to a carrier, the first die comprising:
a first semiconductor substrate;
a first bonding layer over the first semiconductor substrate, wherein the first bonding layer comprises a first portion comprising a first material and a second portion comprising a second material, wherein the first material is different from the second material, and wherein a sidewall of the first portion is in contact with a sidewall of the second portion; and
a first die connector in the first bonding layer; and
bonding a second die to the first die, the second die comprising:
a second semiconductor substrate;
a second bonding layer over the second semiconductor substrate, wherein the second bonding layer comprises a third portion comprising the first material and a fourth portion comprising the second material, and wherein a sidewall of the third portion is in contact with a sidewall of the fourth portion; and
a second die connector in the second bonding layer.

16. The method of claim 15, wherein the first portion is bonded to the fourth portion by dielectric-to-dielectric bonding, wherein the second portion is bonded to the third portion by dielectric-to-dielectric bonding, and wherein the first die connector is bonded to the second die connector by metal-to-metal bonding.

17. The method of claim 16, wherein the first portion is bonded to the third portion by dielectric-to-dielectric bonding.

18. The method of claim 17, wherein the second bonding layer comprises an additional third portion comprising the first material, wherein a sidewall of the additional third portion is in contact with another sidewall of the fourth portion, and wherein the first portion is bonded to the additional third portion by dielectric-to-dielectric bonding.

19. The method of claim 15, wherein the first material is undoped silicate glass (USG), silicon oxide, silicon nitride, or silicon oxynitride, and wherein the second material is undoped silicate glass (USG), silicon oxide, silicon nitride, or silicon oxynitride.

20. The method of claim 15, wherein the first bonding layer further comprises additional first portions comprising the first material and additional second portions comprising the second material, and wherein the first portions and the second portions are arranged in an alternating pattern in a top-down view.
